(19) United States
(12) Patent Application Publication
(10) Pub. No.: US 2005/0254324 A1
(43) Pub. Date: Nov. 17, 2005

(54) Semi-conductor component test procedure, as well as a data buffer component

(75) Inventor: Thorsten Bucksch, Munchen (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 11/114,226

(22) Filed: Apr. 26, 2005

(30) Foreign Application Priority Data
Apr. 28, 2004 (DE) 10 2004 020 867.0

(51) Int. Cl. G11C 29/00

(52) U.S. Cl. 365/201

(57) ABSTRACT

The invention relates to a data buffer component, as well as a semi-conductor component test procedure for testing a memory module with at least one memory component with buffer connected in series before it, whereby the process includes testing the memory modules by using data indicator or data strobe, signals, which have been chronologically advanced or retarded by a pre-determined time period in relation to the memory module during normal operation.

### CLAIM FOR PRIORITY

This application claims priority to German Application No. 10 2004 020 867.0 filed Apr. 28, 2004, which is incorporated herein, in its entirety, by reference.

### TECHNICAL FIELD OF THE INVENTION

The invention relates to a semi-conductor component test procedure, and to a data buffer component.

### BACKGROUND OF THE INVENTION

Semi-conductor components, e.g. corresponding integrated (analog and/or digital) computer circuits, semi-conductor memory components such as for instance function memory components (PLAs, PALs, etc.) and table memory components (e.g. ROMs or RAMs, particularly SRAMs and DRAMs), etc. are subjected to numerous tests during the course of the manufacturing process.

For the simultaneous manufacture of numerous (generally identical) semi-conductor components, a so-called wafer (i.e. a thin disk consisting of monocrystalline silicon) is used. The wafer is appropriately processed (e.g. subjected to numerous, coating, exposure, etching, diffusion and implantation process steps, etc.), and subsequently sawn up (or e.g. scored and snapped off), so that the individual components become available.

During the manufacture of semi-conductor components (e.g. DRAMs (Dynamic Random Access Memories and/or dynamic Read/Write memories), particularly of DDR-DRAMs (Double data Rate—DRAMs and/or DRAMs with double data rate)) the components (still on the wafer and incomplete) may be subjected to corresponding test procedures at one or several test stations by means of one or several test apparatuses (e.g. the so-called kerf measurements at the scoring grid) even before all the required above processing steps have been performed on the wafer (i.e. even while the semi-conductor components are still semi-complete).

After the semi-conductor components have been completed (i.e. after all the above wafer processing steps have been performed) the semi-conductor components are subjected to further test procedures at one or several (further) test stations—for instance the components—still present on the wafer and completed—may be tested with the help of corresponding (further) test apparatuses (“disk tests”).

In corresponding fashion several further tests may be performed (at further corresponding test stations and by using corresponding further test equipment) e.g. after the semi-conductor components have been installed in corresponding semi-conductor-component housings, and/or e.g. after the semi-conductor component housings (together with the semi-conductor components installed in them) have been installed in corresponding electronic modules (so-called “module tests”).

During testing (e.g. during the above disk tests, module tests, etc.), the semi-conductor components, may be subjected to so-called “DC tests” and/or e.g. so-called “AC tests” as test procedures.

During a DC test for instance a voltage (or current) at a specific—in particular a constant—level may be applied to corresponding connections of a semi-conductor component to be tested, whereafter the level of the—resulting—currents (and/or voltages) are measured—in particular tested to see whether these currents (and/or voltages) fall within predetermined required critical values.

During an AC test in contrast, voltages (or currents) at varying levels can for instance be applied to the corresponding connections of a semi-conductor component, particularly corresponding test model signals, with the help of which appropriate function tests may be performed on the semi-conductor component in question.

With the aid of above test procedure defective semi-conductor components and/or modules may be identified and then sorted out (or else partially repaired as well), and/or the process parameters—applied during the manufacture of the components in each case—may be appropriately modified and/or optimized, in accordance with the test results achieved, etc., etc.

In case of numerous applications—e.g. in server or work station computers, etc., etc.—memory modules with data buffer components (so-called buffers) connected in series, e.g. so-called “buffered DIMMs”, may be used.

Similar memory modules generally contain one or several semi-conductor memory components, particularly DRAMs, as well as one or several data buffer components—connected in series before the semi-conductor memory components—such as DRAMs (which may for instance be installed on the same card as the DRAMs).

The memory modules are connected—particularly when a corresponding memory controller has been connected in series (e.g. arranged externally to the memory module in question)—with one or several micro-processors of a particular server or work station computer, etc.

In partially buffered memory modules, the address and control signals of corresponding data buffer components—e.g. emitted by the memory controller, or by the processor in question—may be (briefly) retained and then relayed—in chronologically coordinated, or where appropriate, in de-multiplexed fashion—to the memory components, e.g. DRAMs.

In contrast, the (useful) data signals—emitted by the memory controller and/or by each processor—may be directly—i.e. without being buffered by a corresponding data buffer component (buffer)—relayed to the memory component (and—conversely—the (useful) data signals directly emitted by the memory components may—without a corresponding data buffer component (buffer) being connected in series—relayed to the memory controller and/or to each processor).

With “fully buffered” memory modules in contrast, the address and control signals exchanged between the memory component (and/or each processor) and the memory controller, and also the corresponding (useful) data signals of corresponding data buffer components may first be retained, and only afterwards relayed to the memory component and/or the memory controller or to each processor.

If the above—fully or partially buffered—memory modules are subjected to a corresponding module test, particularly a module function test, the problem arises that the test signals, particularly the test model signals—emitted by the corresponding test apparatus—are totally or partially—decoupled from the memory component by the series-connected data buffer components.

This has the effect that particular parameters of the memory component—e.g. the “data strobe” tolerances—may be not be able to be tested at all and if so, then only inadequately.

### SUMMARY OF THE INVENTION

The invention relates to a semi-conductor component test procedure, as well as a novel data buffer component.

In one embodiment of the invention, there is a semi-conductor component test procedure for testing a memory module with at least one memory component with series-connected buffer is made available, whereby the process includes:
(a) testing the memory module by using data indicator and/or data strobe signals (DQS, DQS#), chronologically advanced or retarded in comparison with the memory module during normal operation by a predetermined time period (τ,+τ1).

Furthermore—in terms of a second embodiment of the invention—a data buffer component is made available, which may be connected in series before a memory component, and which includes:
a device for generating a data indicator or data strobe signal (DQS, DQS#), which device can be switched over from the normal operational mode to a test operational mode, whereby the data indicator and/or data strobe signal (DQS, DQS#) has been chronologically advanced or retarded by a predetermined time period (τ,+τ1) during the test operational mode in comparison with the normal operational mode.

In addition—in terms of a third embodiment of the invention
a data buffer component is made available, which may be connected in series before a memory component and which includes:
a device for receiving a data indicator and/or data strobe signal (DQS, DQS#), which device can be switched over from the normal operational mode to a test operational mode, whereby the data indicator and/or data strobe (DQS, DQS#) is chronologically advanced or retarded by a predetermined time period (τ,+τ1) during the test operational mode in comparison with the normal operational mode.

Advantageously, the data buffer component contains a corresponding device, e.g. a DLL circuit, with which the pulse signal (DQS, DQS#) may be chronologically displaced while in the test operational mode.

### BRIEF DESCRIPTION OF THE DRAWINGS

The invention is described below in more detail with reference to exemplary embodiments as illustrated in the drawings, in which:

FIG. 1 shows a partially buffered memory module, with corresponding memory components, and corresponding data buffer components.

FIG. 2 shows a fully buffered memory module, with corresponding memory components and corresponding data buffer components.

FIG. 3 shows a data buffer component used in the memory module in terms of FIG. 1 and/or 2 to illustrate the functioning of the component during a first alternative version of a semi-conductor component test procedure in terms of an embodiment example of the invention.

FIG. 4 shows a data buffer component used in the memory module in terms of FIG. 1 and/or 2 to illustrate the functioning of the component in a second alternative semi-conductor test procedure in terms of an embodiment example of the invention.

### DETAILED DESCRIPTION OF THE INVENTION

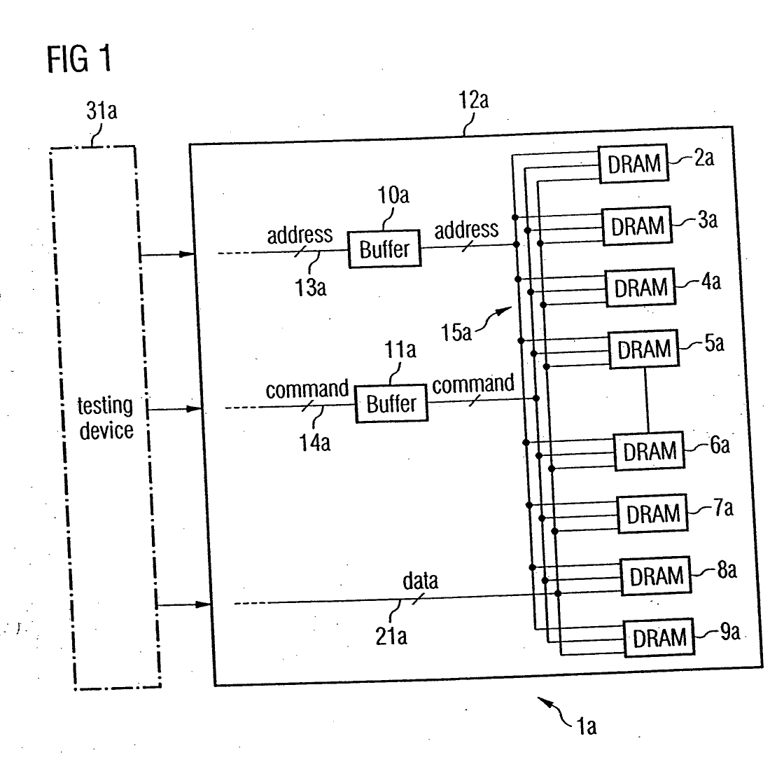

In FIG. 1 a schematic representation of a partially buffered memory module 1a (here: a “buffered DIMM” 1a) is shown.

The memory module includes numerous memory components 2a, 3a, 4a, 5a, 6a, 7a, 8a, 9a, and—connected in series before the memory components 2a, 3a, 4a, 5a, 6a, 7a, 8a, 9a-several (here: two) data buffer components (“buffers”) 10a, 11a.

The memory components 2a, 3a, 4a, 5a, 6a, 7a, 8a, 9a may for instance be function storage or table memory components (e.g. ROMs or RAMs), particularly DRAMs.

Referring to FIG. 1, the memory components 2a, 3a, 4a, 5a, 6a, 7a, 8a, 9a may be arranged on the same card 12a as the buffer 10a, 11a.

The memory module 1a may be connected—particularly with a corresponding memory controller connected in series (e.g. one installed externally to the memory module 1a, in particular one installed externally to the above card 12a and not shown here)—with one or several micro-processors, particularly with one or several micro-processors of a server or work station computer (or of any other suitable micro-processor, e.g. a PC, laptop, etc.).

Referring to FIG. 1, with the partially buffered memory module 1a the address—and control—signals, for instance emitted by the memory controller or the processor in question, are not directly relayed to the memory components 2a, 3a, 4a, 5a, 6a, 7a, 8a, 9a.

Rather, the address signals are first led to the buffers 10a, 11a, for instance via a corresponding address bus 13a, and the control signals for instance via a corresponding control bus 14a (e.g. the address signals—via the address bus 13a—to buffer 10a, and the control signals—via the control bus 14a—to buffer 11a).

The control signals may be any suitable control signals as used in conventional memory modules, e.g. corresponding read and/or write, and/or chip select (memory component selection) signals, etc., etc.

In the buffers 10a, 11a the corresponding signals (address signals, control signals) are—briefly—buffered, and relayed—in a chronologically coordinated, or where needed, demultiplexed fashion—to the memory components 2a, 3a, 4a, 5a, 6a, 7a, 8a, 9a (e.g. via a corresponding—central—memory bus 15a).

With the partially buffered memory module 1a shown in FIG. 1 in contrast, the (useful) data signals—e.g. those emitted by the above memory controller or by the processor in question—may be directly—i.e. without buffering—relayed by a corresponding data buffer component (buffer) to the memory components 2a, 3a, 4a, 5a, 6a, 7a, 8a, 9a (e.g. via a (useful) data bus 21a directly connected with the above central memory bus 15a).

Correspondingly inverted, the (useful) data signals (data)—emitted by the memory components 2a, 3a, 4a, 5a, 6a, 7a, 8a, 9a—may also be relayed directly—without the inter-connection of a corresponding data buffer component (buffer)—to the memory controller and/or to each processor (e.g. again via the above (useful) data bus 21a, which is directly connected with the central memory bus 15a).

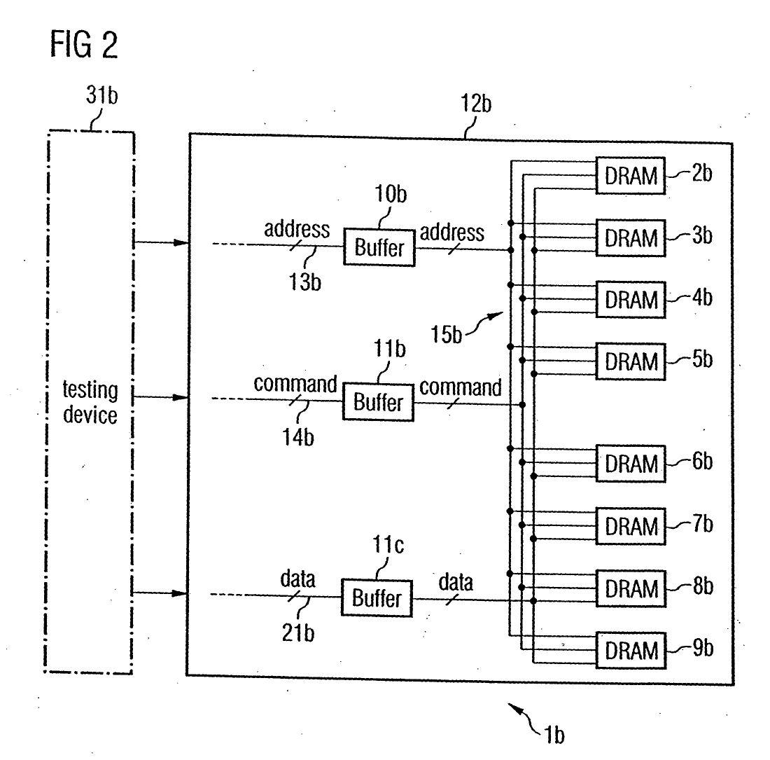

In FIG. 2 a schematic representation of a fully buffered memory module 1b (here: a “buffered DIMM” 1b) is shown.

This includes—corresponding with the partially buffered memory module 1a as in FIG. 1—numerous memory components 2b, 3b, 4b, 5b, 6b, 7b, 8b, 9b and several data buffer components (“buffers”) 10b, 11b, 11c connected in series before the memory components 2b, 3b, 4b, 5b, 6b, 7b, 8b, 9b.

Referring to FIG. 2, the memory components 2b, 3b, 4b, 5b, 6b, 7b, 8b, 9b may be arranged on the same card 12b as the buffers 10b, 11b, 11c.

The memory module 1b may (correspondingly similar to the memory module 1a shown in FIG. 1)—in particular with an inter-connected corresponding memory controller (not shown here and e.g. arranged externally to the memory module 1b, in particular arranged externally to the above card 12)—be connected with one or several micro-processors, particularly with one or several micro-processors of a server or work station computer (or any other suitable micro-processor, e.g. a PC, laptop, etc.).

As is apparent from FIGS. 1 and 2, the memory module 1b shown in FIG. 2 is correspondingly similarly and/or identically constructed with, and operates similarly or identically to the memory module 1a shown in FIG. 1, except that one or several additional data buffer components have been provided (here: an additional buffer 11c), with which—correspondingly similar to conventional fully buffered memory modules−(in addition to the control—and address—signals buffered by the buffers 10b, 11b) the (useful) data signals (data) exchanged between the memory controller, and/or each processor, and the memory components 2b, 3b, 4b, 5b, 6b, 7b, 8b, 9b, are also buffered.

In buffer 11c the corresponding data signals, e.g. those deriving from the memory controller, and/or from each processor, e.g. relayed via a data bus 21b, may also be—briefly—retained and relayed in a chronologically coordinated, or where appropriate, in a multiplexed—or de-multiplexed—fashion to the memory components 2b, 3b, 4b, 5b, 6b, 7b, 8b, 9b (e.g. via a—central—memory bus 15b (corresponding with the above central bus 15a), as described in conjunction with FIG. 1.

Correspondingly inverted, in buffer 11c the data signals emitted by the memory components 2b, 3b, 4b, 5b, 6b, 7b, 8b, 9b to the above central memory bus 15b, may also be—briefly—retained and relayed—in a chronologically coordinated, or where appropriate in a multiplexed or de-multiplexed fashion—to the memory controller and/or each processor (e.g. via the above data bus 21b).

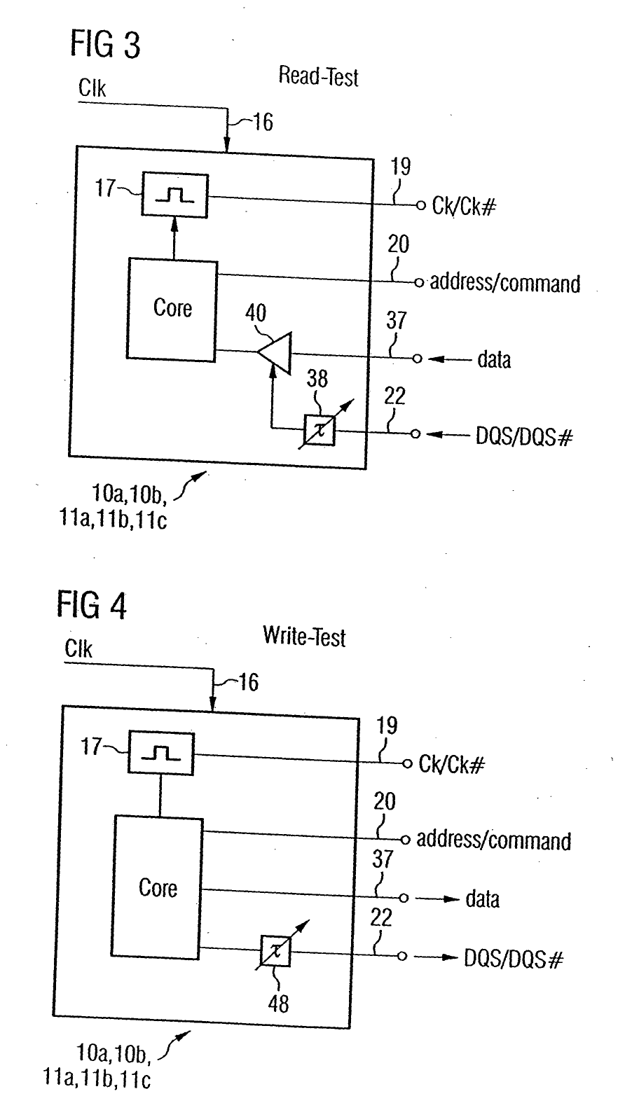

FIG. 3 shows—as an example—a schematic detail representation of a data buffer component and/or buffer 10a, 11a and/or 10b, 11b, 11c, as used in the memory module 1a, 1b in terms of FIG. 1 and/or 2, to illustrate the functioning of the component during a first alternative of a semi-conductor component test procedure in terms of an embodiment example (i.e. during a “read” test).

Corresponding to the above, FIG. 4 shows—also as an example—a schematic detail representation of a data buffer component and/or buffer 10a, 11a and/or 10b, 11b, 11c, to illustrate the functioning of the component during a second alternative of a semi-conductor component test procedure in terms of an embodiment example (i.e. during a “write” test).

As is apparent from FIGS. 3 and 4, one or more of the above buffers 10a, 11a and/or 10b, 11b, 11c (shown in FIG. 1 or 2) may be supplied (e.g. via a corresponding pulse line 16) with an—external—reference pulse signal (clk)(or for instance—via two different pulse lines—with corresponding differential reference pulse signals clk, clk#), for instance from a pulse generator arranged externally to each memory module 1a, 1b and/or externally to each respective card 12a, 12b.

Alternatively, the pulse generator may also be arranged on the same memory module 1a, 1b and/or on the same card 12a, 12b as the memory components 2a, 3a, 4a, 5a, 6a, 7a, 8a, 9a, 2b, 3b, 4b, 5b, 6b, 7b, 8b, 9b and/or the buffers 10a, 11a, and/or 10b, 11b, 11c.

As is illustrated in FIG. 3 and FIG. 4, a pulse signal CK (or corresponding differentiated pulse signals CK, CK#-internally used on the (fully and/or partially buffered memory module 1a, 1b), in particular an internal pulse signal CK (CK#), chronologically coordinated in relation to the external pulse signal (clk), is generated by one or several of the buffers 10a, 11a and/or 10b, 11b, 11c shown in FIG. 1 from the—external—pulse signal (clk).

As is apparent from FIG. 3 and FIG. 4, the internal pulse signal CK (and/or the internal pulse signals CK, CK#) may be emitted by a corresponding pulse signal generating device 17 of the buffers 10a, 11a and/or 10b, 11b, 11c to one (or several) corresponding lines 19 and relayed to the corresponding memory components 2a, 3a, 4a, 5a, 6a, 7a, 8a, 9a, 2b, 3b, 4b, 5b, 6b, 7b, 8b, 9b (and in fact in a fixed predetermined chronological relation to the—external—pulse signal clk).

The signals emitted to corresponding lines 20, 37 by each respective buffer (e.g. the “address” signals emitted by the buffer 10a, 10b and relayed to the central memory bus 15a, 15b, the “command” signals emitted by the buffer 11a, 11b and relayed to the central memory bus 15a, 15b, and the (useful) data signals (“data”) emitted by buffer 11c), stand in a fixed, pre-determined chronological relation to the external pulse signal clk, and to the internal pulse signal CK (and/or to the internal pulse signals CK, CK#) generated by the corresponding buffers 10a, 11a, 10b, 11b, 11c.

The data strobe signals (e.g. a signal DQS, and a signal DQS# inverted in relation to it) for instance exchanged with corresponding lines 22 linking the memory components (similarly connected with the central memory bus) and a corresponding buffer (and/or directly with to the memory controller/processor) serve to indicate when the (useful) data signals emitted by each respective memory component and/or buffer (or directly by the memory controller/processor) are present in a stable state, i.e. for the chronological coordination of the writing of the (useful) data present at the memory bus into the memory component—which is in communication with the respective buffer (and/or memory controller/processor) (“writing process”)—(and/or—conversely—for the chronological coordination of the reading out of the (useful) data present at the memory bus by the buffer (and/or memory controller/processor), which is in communication with the memory component (“reading” process)).

For instance by means of the memory component—emitting the signals DQS and/or DQS# during a “reading process”- and with an appropriate flank change of the signal DQS (e.g. with a positive flank (or a negative flank)), (and with a corresponding flank change of the—inverted—signal DQS# (e.g. with a negative flank (or a positive flank))) it can be shown that the data signals (“data”), corresponding with the data to be read from the memory component) is stable. In contrast during a “transfer pause” the signals DQS and DQS# may remain in their respective previous state (“high logic” or “low logic”) between two successive data and/or data bursts, i.e. no flank change takes place; at the start of the transfer, i.e. before the start of the data burst (and where appropriate also at the end) the signals DQS and DQS# may be in a tri-state condition.

For instance—as shown in FIG. 3—a receiver circuit provided in the respective buffer for preparing the data signals (“data”) present on the above line 37 and emitted by the respective memory component, can be controlled in such a way by the DQS and DQS# signals—received on line 22—that the corresponding data signals are detected and relayed by the receiver circuit 40 at the right instants, particularly when the corresponding signals are stable.

As is apparent from FIG. 3, a signal adjustment device 38 has—in the present embodiment example—a signal adjustment device 38 connected in series between the above lines 22 (at which the signals DQS and/or DQS# are received) and the receiver circuit 40.

This signal adjustment device, as is more closely described below, is—during the normal operation of the memory modules 1a, 1b—deactivated, and relays the signals DQS and/or DQS# present on lines 22 to the receiver circuit 40 without adaptation and/or adjustment, particularly without any delay.

In contrast to this, during the test operation of the memory modules 1a, 1b the signal adjustment device 38—as is more closely described below—can be correspondingly activated, which has the effect of relaying the signals DQS and/or DQS# present on lines 22 to the receiver circuit 40 in suitably adjusted form, especially chronologically delayed (in the positive or negative sense).

In a correspondingly similar fashion to the “reading process”, the buffer emitting the signals DQS and/or DQS# (e.g. to the above line 22) may indicate during a “writing process” that the data signals (“data”)—for instance emitted onto the above line 37—corresponding with the data to be written into the memory component—are (already) stable, or not (yet) stable.

For instance, by means of a negative or positive flank of the signal DQS (and a positive flank (or a negative flank of the—inverted—signal DQS#) it can be shown that the data signals (“data”), are stable. In contrast, during a “transfer pause” the signals DQS and DQS# may remain in their respective previous state (“high logic” or “low logic”) between two successive data and/or data bursts, i.e. no flank change takes place; at the start of the transfer, i.e. before the start of the data burst (and where appropriate also at the end) the signals DQS and DQS# may be in a tri-state condition.

For instance, it can be indicated by means of a positive or negative flank of the signal DQS (and a negative or positive flank of the—inverted—signal DQS#) that the data signals (“data”) are (already) stable. In contrast to this the signals DQS and DQS# may remain their respective states (“high logic” or “low logic”) during a “transfer pause” between two successive data and/or data bursts, i.e. no flank change takes place; at the start of the transfer, i.e. before the start (and where appropriate, also the end) of the data bursts the signals DQS and DQS# may be in the tri-state condition.

As is apparent from FIG. 4, the respective buffer—in the present embodiment example—includes a (further) signal adjustment device 48, which is connected in series before the above line 22 (to which the signals DQS and/or DQS# are emitted by the respective buffer).

This (further) signal adjustment device 48 is, as is more closely described below, deactivated—during the normal operation of the memory modules 1a, 1b-so that the corresponding DQS and/or DQS# signals are then relayed to the respective memory component without adjustment, in particular without any delay.

In contrast to this, the (further) signal adjustment device 48 may—as is more closely described below—may be correspondingly activated during the test operation of the memory modules 1a, 1b, which has the effect that the corresponding signals DQS and/or DQS# made available by the respective buffer are then emitted to the line 22 in appropriately adjusted form, in particular chronologically (positively or negatively) delayed.

The function of the signal adjustment device 38—shown in FIG. 3—and the signal adjustment device 48—shown in FIG. 4 may also—alternatively—be performed by a single signal adjustment device.

Correspondingly similar to the above address, control and (useful) data signals, the data strobe signals (DQS, DQS#) also stand—during the normal operation of the memory modules 1a, 1b, not however during the test operation of the respective memory modules 1a, 1b as more closely described further below—in a fixed predetermined chronological relation to the external pulse signal clk, and to the internal pulse signal CK generated by the corresponding buffers 10a, 11a, 10b, 11b, 11c and the above address, control and (useful) data signals.

If—by means of a semi-conductor component test procedure more closely described below—the functionality of the memory modules 1a, 1b shown in FIGS. 1 and 2 is tested—as is shown by a dotted line in FIGS. 1 and 2—a corresponding external test apparatus 31a, 31b may be connected with the memory modules (which can—e.g. via the above address, control and data buses 13a, 13b, 14a, 14b, 21a, 21b exchange corresponding address, control and data signals—instead of with the above memory controller and/or processors—with the buffers 10a, 10b, 11a, 11b, 11c and/or memory components 2a, 3a, 4a, 5a, 6a, 7a, 8a, 9a, 2b, 3b, 4b, 5b, 6b, 7b, 8b, 9b, and may make this or these external pulse signal(s) clk (and/or clk#) available—instead of to the above pulse generators—to the memory module 1a, 1b, etc.)

Alternatively, the function of the above—external—test apparatuses 31a, 31b can also be taken over by a component (e.g. by an appropriately designed and constructed buffer) installed on the respective memory module itself, i.e. instead of an externally controlled test process, an internal test process controlled by the memory module itself (a so-called “embedded” test) may be performed.

Below—as an example—an embodiment example of a test process controlled by the external test apparatuses 31a, 31b (or internally controlled) is more closely described with reference to FIG. 3:

In a first step—by applying a corresponding signal, e.g. a suitable data model (particularly by the test apparatuses 31a, 31b)—the corresponding memory module 1a, 1b (particularly the corresponding buffer) may be switched over from the above normal operation to test operation (test mode).

Next—for instance again controlled by the above test apparatuses 31a, 31b—by applying corresponding address and control signals to the above address and control bus 13a, 13b, 14a, 14b, and by applying corresponding (test) data—for instance emitted by the test apparatuses 31a, 31b—to the above data bus 21a, 21b (correspondingly similar to normal operation) the corresponding test data may be stored in the memory components 2a, 3a, 4a, 5a, 6a, 7a, 8a, 9a, 2b, 3b, 4b, 5b, 6b, 7b, 8b, 9b.

Next (again e.g. by applying corresponding signals, particularly corresponding data models from the test apparatuses 31a, 31b) the pulse signal adjustment device 18 shown in FIG. 3—which, as described above, is correspondingly deactivated during the normal operation of the buffer—may be activated.

A DLL circuit (DLL=Delay Locked Loop) may e.g. be used as a pulse signal adjustment device 18, with which (in an activated state) the DQS and/or DQS# signal received by the respective buffer 10a, 11a and/or 10b, 11b, 11c, may have a—variably adjustable—positive or negative delay period τ imposed on it (which may for instance amount to a fraction of the time period of the high logic (or low logic) phase of the signal DQS (and/or DQS#)).

Next—e.g. again controlled by the above test apparatuses 31a, 31b and again by applying corresponding address and control signals to the above address and control bus 13a, 13b, 14a, 14b—the test data previously stored in the memory components 2a, 3a, 4a, 5a, 6a, 7a, 8a, 9a, 2b, 3b, 4b, 5b, 6b, 7b, 8b, 9b can be read out again from the memory components (however with a more critical timing than during normal operation, due to the pulse signals DQS, DQS# being deliberately advanced or retarded by the above delay period τ in comparison with normal operation, especially the data signals (“data”)).

Next—e.g. again controlled by the above test apparatuses 31a, 31b—the test data read out may be compared with the test data previously stored in the memory components.

If the read out test data corresponds with the stored data, the function test will—for a particular delay period τ used during the reading of the test data—count as “passed”; if not, as “failed”.

Advantageously, the above storage and reading out of test data would be repeated in succession (i.e. the above test steps would be performed numerous times in succession), whereby the signal DQS and/or DQS# received in each case by the respective buffer during storage (and/or reading out), has in each case been strongly retarded (in the positive or negative sense).

For instance—during a first test run—(e.g. controlled by the test apparatuses 31a, 31b) the pulse signal adjustment device 38, particularly the DLL circuit, may be so adjusted that it imposes a first, relatively minor positive delay period +τ1 on the signal DQS and/or DQS# received from the respective buffers 10a, 11a and/or 10b, 11b, 11c on lines 22.

During a second test run (e.g. one controlled by the test apparatuses 31a, 31b) the pulse signal adjustment device 38, particularly the DLL circuit, may then be adjusted in such a way that it imposes a second, positive delay period +τ2 on the DQS and/or DQS# received on lines 22, which delay is somewhat longer than the delay period +τ1 used during the first test run; during a third test run a third, positive delay period +τ3 may then be used—further increased in comparison with the second, positive delay period +τ2—etc., etc., until one—or several successive—tests (with a delay period τ_{critical,+} allocated to the respective test in each case) counts, in terms of the description above, as “failed”; (the delay period τ_{critical,+} allocated to this test may be regarded as the “top” critical limit, and/or represents an upper measure of tolerance, particularly an upper data strobe read tolerance limit for each respective tested memory module 1a, 1b).

Correspondingly similar—during a further test run—the pulse signal adjustment device 38, particularly the DLL circuit, may be adjusted in such a way that it imposes a further, in this case negative, relatively minor delay period −τ1 on the signal DQS and/or DQS# and—during a subsequent test run—imposes a negative delay period −τ2, which is (relatively) somewhat longer than the delay period τ1 used during the further test run etc., etc., until one—or several successive—tests (with a delay period τ_{critical,-} allocated to the respective test in each case) counts as “failed” in terms of the description above (the delay period τ_{critical,-} allocated to this test may be regarded as the “bottom” critical limit, and/or represents a lower measure of tolerance, particularly a lower data strobe reading tolerance limit for the respective tested memory module 1a, 1b).

Below—as an example—with reference to FIG. 4, a second alternative to the semi-conductor test procedure controlled by the external test apparatuses 31a, 31b (or controlled internally), is more closely described in terms of an embodiment example of the invention (i.e. a “write” test):

In a first step—by applying corresponding signals, e.g. suitable data models (particularly by the test apparatuses 31a, 31b)—the corresponding memory module 1a, 1b (particularly the corresponding buffer) may be switched over from the above normal operation to test operation (test mode).

Next—in a second step—(again e.g. by applying corresponding signals, particularly a corresponding data models by the test apparatuses 31a, 31b) the pulse signal adjustment device 48 shown in FIG. 4—which, as described above was deactivated during the normal operation of the buffer—may be activated.

A DLL circuit (DLL=Delay Locked Loop) may for instance—again—be used as a pulse signal adjustment device 48, with which (in an activated state) the—internal—signal DQS and/or DQS# emitted by the respective buffer 10a, 11a and/or 10b, 11b, 11c, and generated from the external pulse signal clk, may have a—variably adjustable—positive or negative delay period τ imposed on it (which may for instance amount to a fraction of the time period of the high logic (or low logic) phase of the pulse signal DQS (and/or DQS#)).

Next—e.g. again controlled by the above test apparatuses 31a, 31b—by applying corresponding address and control signals to the above address and control bus 13a, 13b, 14a, 14b, and by applying corresponding (test) data—e.g. emitted by the test apparatuses 31a, 31b—to the above data bus 21a, 21b (correspondingly similar to during normal operation), the corresponding test data can be stored in the memory components 2a, 3a, 4a, 5a, 6a, 7a, 8a, 9a, 2b, 3b, 4b, 5b, 6b, 7b, 8b, 9b (however, due in particular to the signal DQS and/or DQS# being deliberately advanced or retarded in relation to the data signals (“data”) in particular by the above delay period τ, with a more critical timing than during normal operation).

Subsequently—e.g. again controlled by the above test apparatuses 31a, 31b, and again by applying corresponding address and control signals to the above address and control bus 13a, 13b, 14a, 14b—the test data previously stored in the memory components may again be read out of the memory components and for instance relayed to the above test apparatuses 31a, 31b.

Advantageously, the above pulse signal adjustment device 48 shown in FIG. 4 (and/or the signal adjustment device 38) can (again) be deactivated (e.g. by applying corresponding signals by means of the test apparatuses 31, 31b, especially corresponding data models) so that when the test data is read from the memory components, the signals DQS and DQS# stand in the chronological relation foreseen for normal operation to the other signals, especially the data signals (“data”).

Next—e.g. again controlled by the above test apparatuses 31a, 31b—the test data last stored in the memory components may be compared with the read out test data.

If the stored test data corresponds with the read out data, the function test will—for a particular delay period τ used during the storage of the test data—count as “passed”; if not, as “failed”.

Advantageously, the above storage and reading out of test data would be repeated in succession (i.e. the above test steps would be performed numerous times in succession), whereby the signals DQS and/or DQS# emitted by the respective buffer has in each case been retarded (in the positive or negative sense) to a varying degree while being stored.

For example—during a first test run—(e.g. controlled by the test apparatuses 31a, 31b) the pulse signal adjustment device 48 shown in FIG. 4, particularly the DLL circuit, may be so adjusted that it imposes a first, relatively minor delay period +τ1 on the signals DQS and/or DQS# emitted by the respective buffer 10a, 11a and/or 10b, 11b, 11c.

During a second test run (e.g. one controlled by the test apparatuses 31a, 31b) the pulse signal adjustment device 48 shown in FIG. 4, particularly the DLL circuit, may then be adjusted in such a way that it imposes a second, positive delay period +τ2 on the DQS and/or DQS# signals, which delay is somewhat longer than the delay period +τ1 used during the first test run; during a third test run a third, positive delay period +τ3 may then be used—further increased in comparison with the second, positive delay period +τ2—etc., etc., until one—or several successive—tests (with a delay period τ_{critical,+} allocated to the respective test in each case) counts, in terms of the description above, as “failed”; (the delay period τ_{critical,+} allocated to this test may be regarded as the “top” critical limit, and/or represents an upper measure of tolerance, particularly an upper input setup and/or input hold measure of tolerance for the respective tested memory module 1a, 1b).

Correspondingly similar—during a further test run—the pulse signal adjustment device 48, particularly the DLL circuit, may be adjusted in such a way that it imposes a further, in this case negative, relatively minor delay period −τ1 on the DQS and/or DQS# signal, and—during a subsequent test run—imposes a negative delay period −τ2, which is (relatively) somewhat longer than the delay period −τ1 used during the further test run etc., etc., until one—or several successive—tests (with a delay period τ_{critical,-} allocated to the respective test in each case) counts as “failed” in terms of the description above (the delay period τ_{critical,-} allocated to this test may be regarded as the “bottom” critical limit, and/or represents a lower measure of tolerance, particularly a lower data strobe write measure of tolerance for the respective tested memory module 1a, 1b).

Advantageously, the above test procedure illustrated in FIGS. 3 and 4 may be performed for numerous memory modules—correspondingly similarly or identically constructed to the memory modules 1a, 1b shown in FIGS. 1 and 2—(e.g. for numerous mass-produced memory modules of one and the same series),i.e. a corresponding serial test can be undertaken.

Preferably—even during the serial tests—the tolerance parameters τ_{critical,-} and/or τ_{critical,+} measured for the respective memory modules may be subjected to a corresponding assessment.

In this way a corresponding parameter drift may be identified, whereupon suitable remedial measures may—in good time—be instituted (e.g. in the shape of an adjustment to and/or modification of the process parameters applied during the manufacture of the components/modules.)

1. A semi-conductor component test procedure for testing a memory module with at least one memory component with series-connected buffers, comprising testing the memory module by using data indicator and/or data strobe signals, chronologically advanced or retarded in comparison with the memory module during normal operation by a predetermined time period.

2. The process according to claim 1, whereby the data indicator and/or data strobe signals are emitted by the buffer in a chronological relation to corresponding pulse signals.

3. The process according to claim 1, whereby the data indicator and/or data strobe signals are relayed to the memory component by the buffers.

4. The process according to claim 1, whereby the indicator and/or data strobe signals are emitted by the memory component in a chronological relation to the corresponding pulse signal.

5. The process according to claim 1, whereby the data indicator and/or data strobe signals are relayed by the memory component to the buffers.

6. The process according to claim 1, whereby the buffers are configured to be switched over from a normal operational mode to a test operational mode.

7. The process according to claim 6, whereby the buffers include a pulse signal adjustment device, which causes the data indicator and/or data strobe signals relayed to the buffer or emitted by the buffer during the test operating mode, to be chronologically advanced or retarded in relation to the normal operating mode by the predetermined time period.

8. The process according to claim 1, further comprising:
renewed testing of the memory modules by using data indicator and/or data strobe signals chronologically advanced or retarded by a second predetermined time period in comparison with the memory module during normal operation, whereby the second, predetermined time period differs from the first predetermined time period used during the testing.

9. The process according to claim 1, whereby the memory module is tested repeatedly and in each case by using predetermined data indicator and/or data strobe signals which have been chronologically advanced or retarded in comparison with the memory module during normal operation by varying predetermined time periods.

10. A data buffer component configured to be connected in series before a memory component and comprising a device for generating a data indicator and/or data strobe signal, which is configured to be switched over from a normal operating mode to a test operating mode, whereby a pulse signal in a test operating mode has been chronologically advanced or retarded in relation to normal operating mode by a predetermined time period.

11. A data buffer component configured to be connected in series before a memory component and comprising a device for receiving a data indicator and/or data strobe signal, which is configured to be switched over from a normal operational mode to a test operational mode, whereby the data indicator and/or data strobe signal in a test operational mode has been chronologically advanced or retarded in relation to normal operational mode by a predetermined time period.

12. The data buffer component according to claim 10, which includes another device for chronologically varying the pulse signals during the test operational mode.

13. The data buffer component according to claim 12, in which the device includes a DLL circuit for the chronological displacement of the data indicator and/or data strobe signals during the test operational mode.

14. The data buffer component according to claim 11, which includes another device for chronologically varying the pulse signals during the test operational mode.
